(19) United States
(12) Patent Application Publication
(10) Pub. No.: US 2008/0072822 A1
(43) Pub. Date: Mar. 27, 2008

(54) SYSTEM AND METHOD INCLUDING A PARTICLE TRAP/FILTER FOR RECIRCULATING A DILUTION GAS

(76) Inventor: JOHN M. WHITE, Hayward, CA (US)

Correspondence Address: PATTERSON & SHERIDAN, LLP, 3040 POST OAK BOULEVARD, SUITE 1500, HOUSTON, TX, 77056, US

(21) Appl. No.: 11/846,359

(22) Filed: Aug. 28, 2007

Related U.S. Application Data
(60) Provisional application No. 60/826,718, filed on Sep. 22, 2006.

(51) Int. Cl. C23C 16/00; B01D 53/14

(52) U.S. Cl. 118/722; 427/248.1; 96/108

(57) ABSTRACT

The present invention comprises a method and an apparatus that include a particle trap/filter for recirculating a processing gas through a system. The processing gas may be evacuated from the chamber and may pass through a particle trap/filter. A portion of the gas may recirculate back to the processing chamber while another portion of the process gas may be evacuated through mechanical backing pumps. As the processing gas flows through the particle trap/filter, contaminant substances may be captured by a filter medium inside the particle trap/filter. The recirculated portion of the processing gas may then join fresh, unrecirculated process gas and enter the processing chamber. The recirculated gas may join the fresh, unrecirculated processing gas after the fresh, unrecirculated processing gas has passed through a remote plasma source. The plasma generated in the remote plasma source may ensure that the recirculated process gas does not deposit on the conduits leading into the process chamber. The amount of gas recirculated may determine the amount of fresh, unrecirculated process gas that may be delivered to the process chamber.

### CROSS-REFERENCE TO RELATED APPLICATIONS

This application claims benefit of U.S. provisional patent application Ser. No. 60/826,718 (APPM/011402L), filed Sep. 22, 2006, which is herein incorporated by reference.

### BACKGROUND OF THE INVENTION

1. Field of the Invention

Embodiments of the present invention generally relate to a method and apparatus for recirculating process gases in a plasma enhanced chemical vapor deposition (PECVD) process.

2. Description of the Related Art

PECVD is a method for depositing a material onto a substrate by exciting process gases into a plasma state. Process gases may be continually provided to the chamber until a desired thickness of the material deposited is achieved. During processing, the process gases may be exhausted from the process chamber in order to maintain a constant pressure within the chamber. Therefore, there is a need in the art to provide process gases to a PECVD chamber and exhaust gases from a PECVD chamber in an efficient, cost effective manner.

### SUMMARY OF THE INVENTION

The present invention comprises a method and an apparatus that include a particle trap/filter for recirculating a processing gas through a system. The processing gas may be evacuated from the chamber and may pass through a particle trap/filter. A portion of the gas may recirculate back to the processing chamber while another portion of the process gas may be evacuated through mechanical backing pumps. As the processing gas flows through the particle trap/filter, contaminant substances may be captured by a filter medium inside the particle trap/filter. The recirculated portion of the processing gas may then join fresh, unrecirculated process gas and enter the processing chamber. The recirculated gas may join the fresh, unrecirculated processing gas after the fresh, unrecirculated processing gas has passed through a remote plasma source. The plasma generated in the remote plasma source may ensure that the recirculated process gas does not deposit on the conduits leading into the process chamber. The amount of gas recirculated may determine the amount of fresh, unrecirculated process gas that may be delivered to the process chamber.

In one embodiment, a particle trap/filter assembly is disclosed. The assembly comprises a particle trap/filter body having an inlet adapted to be coupled with a chamber outlet and an outlet adapted to be coupled with a chamber inlet, a filter medium disposed within the body between the inlet and the outlet, and a heat exchange circuit coupled with the filter medium.

In another embodiment, a plasma enhanced chemical vapor deposition apparatus is disclosed. The apparatus comprises a gas source, a processing chamber having a chamber outlet and a chamber inlet, and a recirculation system including a particle trap/filter assembly. The assembly comprises a particle trap/filter body having an inlet adapted to be coupled with the chamber outlet and an outlet adapted to be coupled with the chamber inlet, a filter medium disposed within the body between the inlet and the outlet, and a heat exchange circuit coupled with the filter medium.

In still another embodiment, a plasma enhanced chemical vapor deposition method is disclosed. The method comprises providing a fresh, unrecirculated processing gas to a plasma enhanced chemical vapor deposition chamber having a chamber inlet and a chamber outlet, performing a plasma enhanced chemical vapor deposition process, exhausting the processing gas from the chamber, flowing the exhausted processing gas through a particle trap/filter assembly, and recirculating at least a portion of the exhausted processing gas back to the chamber. The assembly comprises a particle trap/filter body having an inlet coupled with the chamber outlet, an outlet coupled with the chamber inlet, a filter medium disposed within the body between the inlet and the outlet, and a heat exchange circuit coupled with the filter medium.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a sectional view of a PECVD chamber 100 that may be used in connection with one or more embodiments of the invention;

FIG. 2 is a schematic drawing of a dilution gas recirculation system 200 according to one embodiment of the invention;

FIG. 3 is a schematic drawings of a particle trap/filter 300 according to one embodiment of the invention; and

FIG. 4 is a schematic drawing of a particle trap/filter 400 according to another embodiment of the invention.

FIG. 5 is a schematic drawing of a particle trap filter 500 according to another variant embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention comprises a method and an apparatus that include a particle trap/filter for recirculating a processing gas through a system. The processing gas may be evacuated from the chamber and may pass through a particle trap/filter. A portion of the gas may recirculate back to the processing chamber while another portion of the process gas may be evacuated through mechanical backing pumps. As the processing gas flows through the particle trap/filter, contaminant substances may be captured by a filter medium inside the particle trap/filter. The recirculated portion of the processing gas may then join fresh, unrecirculated process gas and enter the processing chamber. The recirculated gas may join the fresh, unrecirculated processing gas after the fresh, unrecirculated processing gas has passed through a remote plasma source. The plasma generated in the remote plasma source may ensure that the recirculated process gas does not deposit on the conduits leading into the process chamber. The amount of gas recirculated may determine the amount of fresh, unrecirculated process gas that may be delivered to the process chamber.

### PECVD System

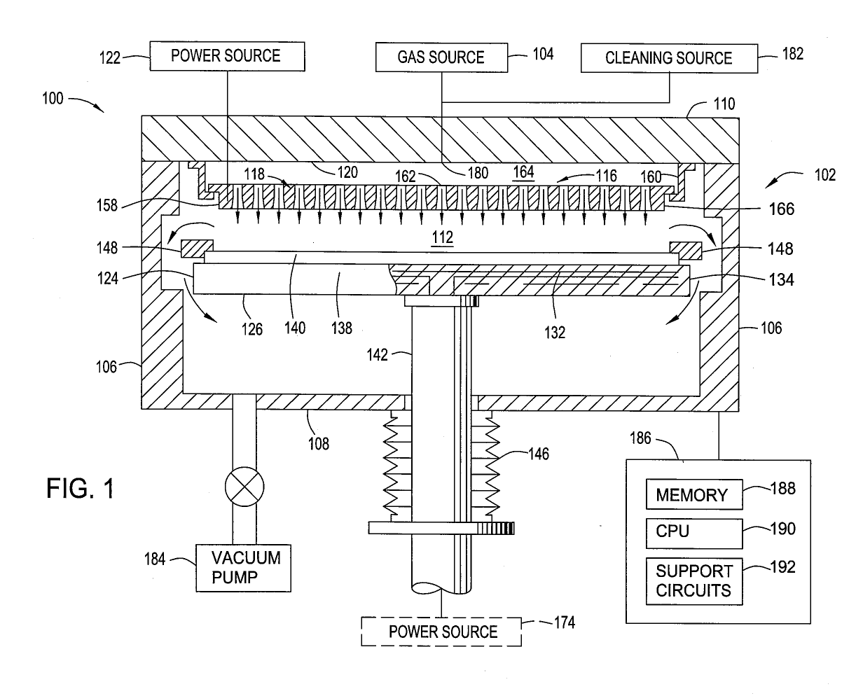

FIG. 1 is a schematic cross-sectional view of one embodiment of a PECVD system 100, available from AKT, a division of Applied Materials, Inc., Santa Clara, Calif. It is to be understood that the invention may be practiced on other processing systems that necessitate introducing a gas into the chamber, including those processing systems produced by other manufacturers. The system 100 may include a processing chamber 102 coupled to a gas source 104. The processing chamber 102 has walls 106 and a bottom 108 that partially define a process volume 112. The process volume 112 may be accessed through a port (not shown) in the walls 106 that facilitate movement of a substrate 140 into and out of the processing chamber 102. The walls 106 and bottom 108 may be fabricated from a unitary block of aluminum or other material compatible with processing. The walls 106 support a lid assembly 110. The processing chamber 102 may be evacuated by a vacuum pump 184.

A temperature controlled substrate support assembly 138 may be centrally disposed within the processing chamber 102. The support assembly 138 may support a substrate 140 during processing. In one embodiment, the substrate support assembly 138 comprises an aluminum body 124 that encapsulates at least one embedded heater 132. The heater 132, such as a resistive element, disposed in the support assembly 138, may be coupled to a power source 174 and controllably heats the support assembly 138 and the substrate 140 positioned thereon to a predetermined temperature. The heater 132 may maintain the substrate 140 at a uniform temperature between about 150 degrees Celsius to at least about 460 degrees Celsius, depending on the deposition processing parameters for the material being deposited.

The substrate support assembly 138 may include a two zone embedded heater. One zone may be an inner heating zone that is located near the center of the substrate support assembly 138. The outer heating zone may be located near the outer edge of the substrate support assembly 138. The outer heating zone may be set to a higher temperature to compensate the higher thermal losses that may occur at the edge of the substrate support assembly 138. An exemplary two zone heating assembly that may be used to practice the present invention is disclosed in U.S. Pat. No. 5,844,205, which is hereby incorporated by reference in its entirety.

The support assembly 138 may have a lower side 126 and an upper side 134. The upper side 134 supports the substrate 140. The lower side 126 may have a stem 142 coupled thereto. The stem 142 couples the support assembly 138 to a lift system (not shown) that moves the support assembly 138 between an elevated processing position (as shown) and a lowered position that facilitates substrate transfer to and from the processing chamber 102. The stem 142 additionally provides a conduit for electrical and thermocouple leads between the support assembly 138 and other components of the system 100.

A bellows 146 may be coupled between support assembly 138 (or the stem 142) and the bottom 108 of the processing chamber 102. The bellows 146 provides a vacuum seal between the chamber volume 112 and the atmosphere outside the processing chamber 102 while facilitating vertical movement of the support assembly 138.

The support assembly 138 may be grounded such that RF power supplied by a power source 122 to a gas distribution plate assembly 118 positioned between the lid assembly 110 and substrate support assembly 138 (or other electrode positioned within or near the lid assembly of the chamber) may excite gases present in the process volume 112 between the support assembly 138 and the distribution plate assembly 118. The RF power from the power source 122 may be selected commensurate with the size of the substrate to drive the chemical vapor deposition process.

The support assembly 138 may additionally support a circumscribing shadow frame 148. The shadow frame 148 may prevent deposition at the edge of the substrate 140 and support assembly 138 so that the substrate may not stick to the support assembly 138.

The lid assembly 110 provides an upper boundary to the process volume 112. The lid assembly 110 may be removed or opened to service the processing chamber 102. In one embodiment, the lid assembly 110 may be fabricated from aluminum.

The lid assembly 110 may include an entry port 180 through which process gases provided by the gas source 104 may be introduced into the processing chamber 102. The entry port 180 may also be coupled to a cleaning source 182. The cleaning source 182 may provide a cleaning agent, such as disassociated fluorine, that may be introduced into the processing chamber 102 to remove deposition by-products and films from processing chamber hardware, including the gas distribution plate assembly 118.

The gas distribution plate assembly 118 may be coupled to an interior side 120 of the lid assembly 110. The gas distribution plate assembly 118 may be configured to substantially follow the profile of the substrate 140, for example, polygonal for large area flat panel substrates and circular for substrates. The gas distribution plate assembly 118 may include a perforated area 116 through which process and other gases supplied from the gas source 104 may be delivered to the process volume 112. The perforated area 116 of the gas distribution plate assembly 118 may be configured to provide uniform distribution of gases passing through the gas distribution plate assembly 118 into the processing chamber 102. Gas distribution plates that may be adapted to benefit from the invention are described in commonly assigned U.S. Pat. Nos. 6,477,980; 6,772,827; 7,008,484; 6,942,753 and United States Patent Published Application Nos. 2004/0129211 A1, which are hereby incorporated by reference in their entireties.

The gas distribution plate assembly 118 may include a diffuser plate 158 suspended from a hanger plate 160. The diffuser plate 158 and hanger plate 160 may alternatively comprise a single unitary member. A plurality of gas passages 162 may be formed through the diffuser plate 158 to allow a predetermined distribution of gas passing through the gas distribution plate assembly 118 and into the process volume 112. The hanger plate 160 maintains the diffuser plate 158 and the interior surface 120 of the lid assembly 110 in a spaced-apart relation, thus defining a plenum 164 therebetween. The plenum 164 may allow gases flowing through the lid assembly 110 to uniformly distribute across the width of the diffuser plate 158 so that gas may be provided uniformly above the center perforated area 116 and flow with a uniform distribution through the gas passages 162.

The diffuser plate 158 may be fabricated from stainless steel, aluminum, anodized aluminum, nickel or any other RF conductive material. The diffuser plate 158 may be configured with a thickness that maintains sufficient flatness across the aperture 166 as not to adversely affect substrate processing. In one embodiment the diffuser plate 158 may have a thickness between about 1.0 inch to about 2.0 inches. The diffuser plate 158 may be circular for semiconductor substrate manufacturing or polygonal, such as rectangular, for flat panel display manufacturing.

As shown in FIG. 1, a controller 186 may interface with and control various components of the substrate processing system. The controller 186 may include a central processing unit (CPU) 190, support circuits 192 and a memory 188.

The processing gas may enter into the chamber 102 from the gas source 104 and be exhausted out of the chamber 102 by a vacuum pump 184. As will be discussed below, fresh, unrecirculated process gas may be provided from the gas source 104 to the chamber 102 through a remote plasma source (not shown). Portions of the gas evacuated from the chamber 102 may pass through at least a particle trap/filter and then be recirculated back to the chamber 102. The recirculated processing gas may connect back to the chamber 102 at a location after the remote plasma source. Exemplary gases that may be recirculated include H₂, silanes, PH₃, or TMB.

### Recirculation System

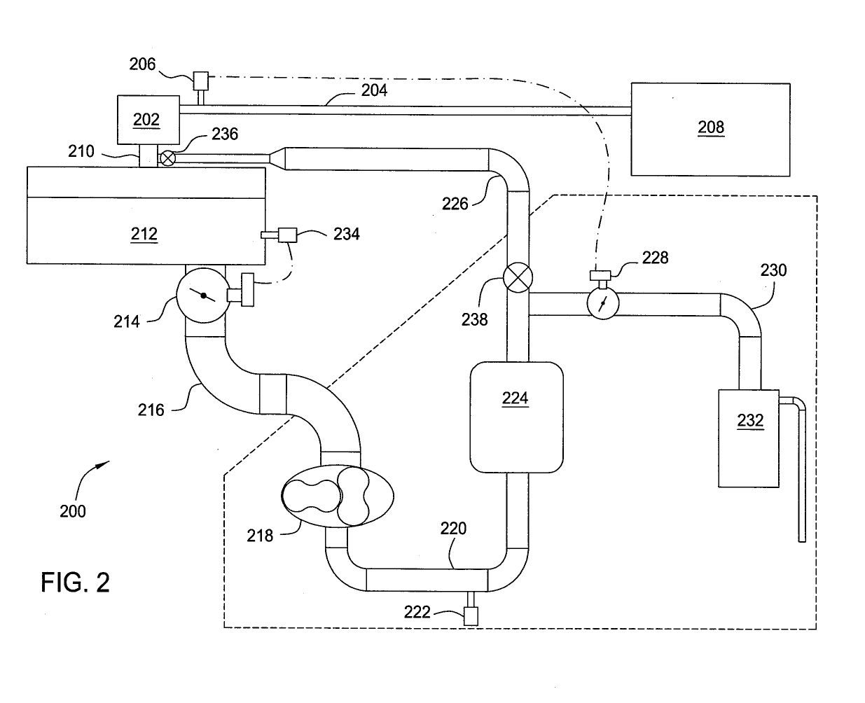

FIG. 2 is a drawing showing one embodiment of a dilution gas recirculation system 200. As may be seen from FIG. 2, a process gas may initially be provided to a processing chamber 212 from a gas source 208 through inlet conduits 204, 210. A remote plasma source 202 may be positioned along the inlet conduits 204, 210 to strike a plasma remotely from the process chamber 212. By striking a plasma remotely from the chamber 212, the plasma generated in the remote plasma source 202 may pass through the inlet conduit 210 and keep the inlet conduit 210 free of deposits.

The processing chamber 212 may be evacuated to remove the processing gases. One or more mechanical backing pumps 232 may be positioned to evacuate the processing chamber 212. One or more pressure boosting devices 218 may additionally be provided between the processing chamber 212 and the one or more mechanical backing pumps 232 to aid in evacuating the chamber 212. In one embodiment, the pressure boosting device 218 may be a roots blower. In another embodiment, the pressure boosting device 218 may be a mechanical pump. Additionally, a pressure boosting device 218 may be positioned along the conduit 226 back to the processing chamber 212. A chamber pressure gauge 234 may be coupled with the processing chamber 212 to measure the pressure within the processing chamber 212. A chamber throttle valve 214 may be positioned along the exit conduit 216. The chamber throttle valve 214 may be coupled with the chamber pressure gauge 234. Based upon the pressure as measured at the chamber pressure gauge 234, the amount that the chamber throttle valve 214 is opened may be adjusted. By coupling the chamber throttle valve 214 and the chamber pressure gauge 234 together, a predetermined chamber pressure may be maintained. In one embodiment, the chamber pressure may be about 0.3 Torr to about 25 Torr. In another embodiment, the chamber pressure may be about 0.3 Torr to about 15 Torr.

A portion of the evacuated processing gas may be recirculated back to the processing chamber 212. The evacuated processing gas passes through the chamber throttle valve 214 and the roots blower 218 along conduits 216, 220 to a particle trap/filter 224. The pressure of the process gas within the conduit 220 may be measured with an exhaust pressure gauge 222 positioned along the conduit 220. The particle trap/filter 224 is adapted to capture contaminant substances present within the evacuated processing gas, such as byproduct particulates and oil substances that may come from the pumps 232, roots blower 218, or various valves. By reducing the amount of contaminants present within the processing gas, the amount of deposition that may occur in conduits 226, 210 leading to the processing chamber 212 may be reduced.

A shut-off valve 238 may be positioned at a location of the recirculation conduit 226 downstream from the particle trap/filter 224. The shut-off valve 238 may be turned to a closed state for evacuating a gas that has passed through the particle trap/filter 224 and needs not be recirculated toward the process chamber 212.

The amount of processing gas that is recirculated may be controlled by a recirculation throttle valve 228. The amount that the recirculation throttle valve 228 is opened, coupled with the opening of the shut-off valve 238, determines the amount of processing gas that may be recirculated and the amount of processing gas that may be evacuated to the mechanical backing pumps 232 through the conduit 230. The more that the recirculation throttle valve 228 is opened, the more processing gases that are evacuated to the mechanical backing pumps 232. The less that the recirculation throttle valve 228 is opened, the more processing gas is recirculated back to the processing chamber 212. A shut-off valve 236 may be positioned where the recirculation conduit 226 joins the conduit 210 leading to the processing chamber 210 so that, as desired, the recirculation may be prevented.

The recirculation throttle valve 228 may be coupled with the inlet pressure gauge 206. By coupling the inlet pressure gauge 206 to the recirculation throttle valve 228, the amount that the recirculation throttle valve 228 is opened may be controlled based upon the pressure as measured at the inlet pressure gauge 206. Hence, the amount of gas recirculated is a function of the pressure as measured at the inlet pressure gauge 206. In one embodiment, the pressure as measured at the inlet pressure gauge 206 may be about 1 Torr to about 100 Torr. In another embodiment, the pressure as measured at the inlet pressure gauge 206 may be about 1 Torr to about 20 Torr. A desired mass flow rate of processing gas to the processing chamber 212 may be controlled. Once a desired mass flow rate to the processing chamber 212 is determined, the mass flow rate of fresh, unrecirculated processing gas may be set and the amount of processing gas recirculated may be adjusted as a function of the fresh, unrecirculated processing gas so that the combined flow of the fresh, unrecirculated processing gas and the recirculated processing gas equals the desired mass flow rate to the chamber 212.

The recirculated processing gas may join with the fresh, unrecirculated processing gas at a location between the remote plasma source 202 and the processing chamber 212. By providing the recirculated processing gases after the remote plasma source 202, deposition along the inlet conduit 210 that may result due to the presence of the recirculated gas may be reduced. Additionally, the plasma generated in the remote plasma source 202 may clean away deposits that may form within the inlet conduit 210 due to the presence of the recirculated gases.

### Particle Trap/Filter

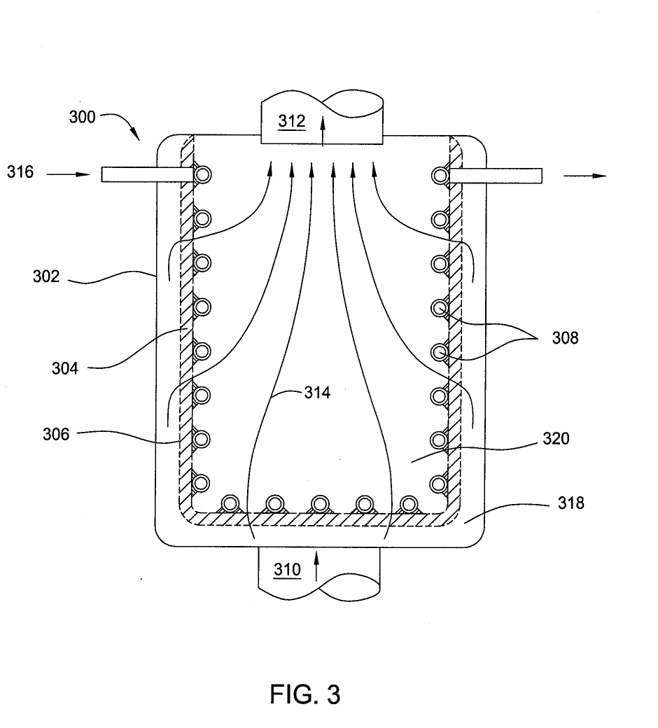

FIG. 3 is a schematic drawing illustrating one embodiment of a particle trap/filter 300. The particle trap/filter 300 comprises a housing 302 having an interior volume communicating with a gas inlet 310 and a gas outlet 312, and a filter medium 304 assembled within the housing 302. The housing 302 may be fabricated from aluminum or other compatible materials. In one embodiment, the housing 302 may comprise stainless steel. The assembly of the filter medium 304 within the housing 302 divides its interior volume into an inner volume 320 substantially enclosed by the filter medium 304, and an outer volume 318 that substantially surrounds the inner volume 320. As indicated with the gas flow direction 314, the processing gas enters the housing 302 via the gas inlet 310, flows from the outer volume 318 through the filter medium 304 into the inner volume 320, and then exits the particle trap/filter 300 via the gas outlet 312.

The filter medium 304 may be made of nickel, stainless steel, or other compatible metal alloys cleanable with a plasma, such as a fluorine based cleaning gas, or a combination thereof. In one embodiment, the filter medium 304 may comprise 316 stainless steel. The filter medium 304 may have about 20 percent to about 30 percent open area. In one embodiment, the cleaning gas may comprise SF₆, NF₃, or F₂. The filter medium 304 may be provided with perforations 306 that are suitably sized to permit the flow 314 of the processing gas from the outer volume 318 into the inner volume 320, while blocking the passage of particulates present in the processing gas. In one embodiment, the filter medium 304 may be provided with a gas selective permeable membrane that permits a particular gas to pass through the medium while preventing a different gas from passing through the medium. The size of the trapped particulates may depend on the configuration of the perforations 306, and may have an area of about 1 micron in one embodiment. Furthermore, one side of the filter medium 304 includes a heat exchange circuit 308 that may be attached to the filter medium 304 by diffusion bonding or welding. In one embodiment, the heat exchange circuit 308 may be made of a same material as the filter medium 304. Either a cooling or heating fluid supplied from an external source 316 may be circulated to control the temperature state of the filter medium 304. More specifically, a coolant such as water or other adequate cooling fluids may be flowed through the heat exchange circuit 308 when the particle trap/filter 300 is operating in a filtering mode. As the processing gas flows through the cooled filter medium 304, particulates may be effectively captured and pump oil vapors present in the processing gas may be condensed and trapped on the surface of the filter medium 304.

To clean the particle trap/filter 300, a plasma and/or cleaning gas including SF₆, NF₃, or F₂ may be flowed inside the housing 302 from the gas inlet 310 to etch residues accumulated within the housing 302, and on the filter medium 304. While the plasma and cleaning gas are flowed through the particle trap/filter 300, a heating fluid may also be circulated through the heat exchange circuit 308 to raise the temperature of the filter medium 304. Certain residues captured within the particle trap/filter 300, such as condensed oil and silicon ammonium hexafluoride, thereby may be alternatively removed by evaporation and sublimation.

In one embodiment, the plasma and cleaning gas may be generated by the remote plasma source 202 and gas panel 208 shown in FIG. 2. The particle trap/filter 224 thereby can be conveniently cleaned as the plasma and cleaning gas flow downstream through the recirculation system. The particle trap/filter 224 thus may be periodically cleaned without the need for replacement of filter elements.

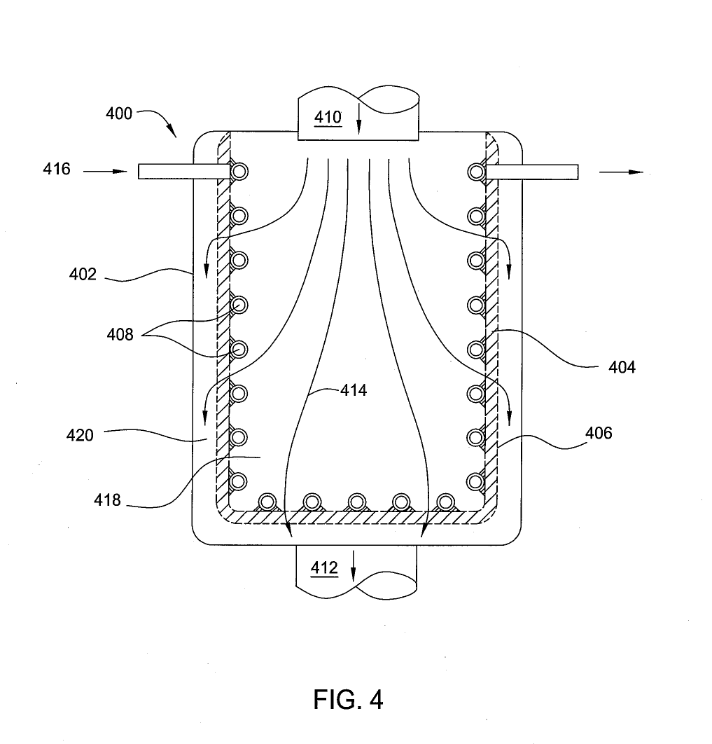

FIG. 4 illustrates another embodiment of a particle trap/filter 400. Like the embodiment shown in FIG. 3, the particle trap/filter 400 includes a housing 402, a filter medium 404 with perforations 406 that divide the interior volume of the housing 402 into an inner volume 418 and a surrounding outer volume 420, and a heat exchange circuit 408 coupled to an external source 416. The particle trap/filter 400 differs from the embodiment of FIG. 3 in that the inner volume 418 communicates with a gas inlet 410, while the outer volume 420 communicates with the gas outlet 412. As indicated with the gas flow direction 414, the processing gas enters the housing 402 via the gas inlet 410, flows from the inner volume 418 through the filter medium 404 into the outer volume 420, and then exits the particle trap/filter 400 via the gas outlet 412. One side of the filter medium 404 includes a heat exchange circuit 408 that may be attached to the filter medium 404 by diffusion bonding or welding. In one embodiment, the heat exchange circuit 408 may be made of a same material as the filter medium 404.

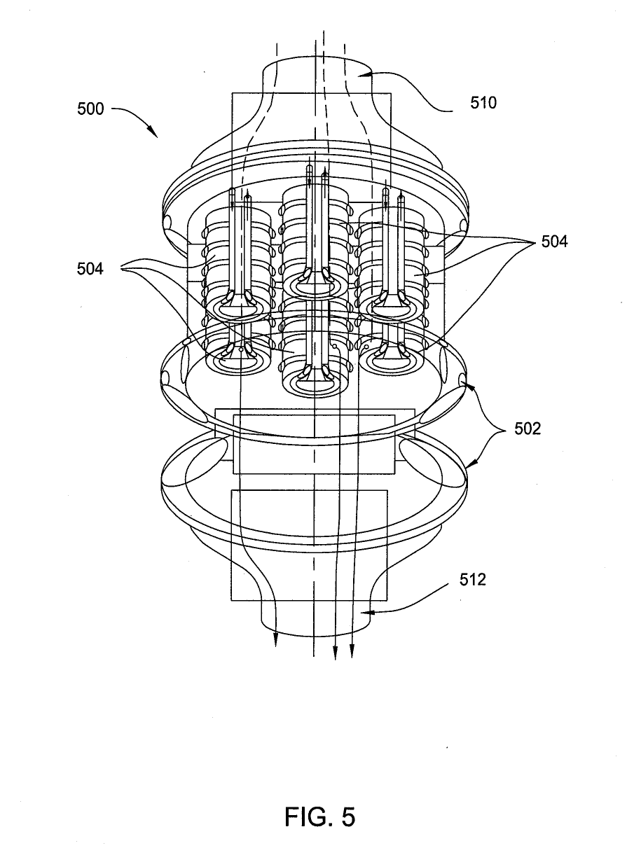

FIG. 5 illustrates another embodiment of a particle trap/filter 500. The particle trap/filter 500 comprises a housing 502 having an interior volume communicating with a gas inlet 510 and a gas outlet 512. The housing is shown open and transparent for clarity. The interior volume of the housing 502 assembles a plurality of particle trap/filter unit 504. The construction of each particle trap/filter unit 504 may be similar to either of the particle trap/filter 300 shown in FIG. 3 or particle trap/filter 400 shown in FIG. 4. The gas flow enters the housing via the gas inlet 510, flows through each of the particle trap/filter units 504, and exits through the gas outlet 512. The heat exchange circuits within the individual particle traps/filters 504 may be attached to the filter medium by diffusion bonding or welding. In one embodiment, the heat exchange circuit may be made of a same material as the filter medium.

The PECVD system described above may be used to deposit films on substrates such as solar panel substrates. Such films may include silicon containing films such as p-doped silicon layers (P-type), n-doped silicon layers (N-type), or intrinsic silicon layers (I-type) deposited to form a P-I-N based structure. The silicon containing films may be amorphous silicon, microcrystalline silicon, or polysilicon. An operation of a recirculation system will be discussed hereafter with reference to FIGS. 2 and 3, but it should be understood that the recirculation system shown in FIG. 4 is equally applicable.

At startup, the recirculation system is not yet running and the recirculation throttle valve 228 is fully open to allow all processing gases to be exhausted to the mechanical backing pumps 232. Fresh processing gas may be delivered from the gas source 208 to the remote plasma source 202 through the conduit 204. The fresh processing gas may include deposition gases, inert gases, and diluting gases such as hydrogen gas. The gases may be provided to separate conduits 204 to the remote plasma source 202 or through a single conduit 204. In one embodiment, the deposition gases may be plumbed directly to the processing chamber 212 which the diluting gas and the inert gas may be provided directly to the remote plasma source 202.

The inlet pressure gauge 206 measures and controls the amount of fresh processing gas that is provided to the remote plasma source 202. After a plasma is struck in the remote plasma source 202, the processing gas continues to the processing chamber 212 where deposition may occur. The processing gas, once used, is evacuated from the processing chamber 212 through a conduit 216 by mechanical backing pumps 232. A chamber pressure gauge 234 measures the pressure within the processing chamber 212. In order to maintain the proper pressure within the processing chamber 212, a chamber throttle valve 214 may be opened or closed based upon the pressure measured at the chamber pressure gauge 234. One or more pressure boosting devices 218 may be positioned between the processing chamber 212 and the backing pumps 232.

The used processing gas may then flow through a particle trap/filter 224 where particulates and oil substances may be removed from the gas. The recirculation throttle valve 228 may be fully opened to permit all of the processing gas evacuated from the processing chamber 212 to be evacuated from the system upon process initiation. However, as the process proceeds and the desired chamber pressure is achieved and maintained, the recirculation of the processing gas may be enabled by opening the shut-off valve 238. The recirculation throttle valve 228 then may close partially or entirely. The amount that the recirculation throttle valve 228 is opened or closed is a function of the pressure as measured at the inlet pressure gauge 206.

As shown in FIG. 3, one embodiment of a particle trap/filter 300 may have a filter medium 304 that can be cooled by a heat exchange circuit 308 for capturing contaminant substances from the recirculated processing gas. More particularly, oil substances that may be present in the recirculated processing gas in a vapor phase can be thereby condensed and captured by the cooled filter medium 304.

As the recirculation throttle valve 228 is closed, the amount of fresh, unrecirculated processing gas that is provided to the remote plasma source 202 is correspondingly reduced to ensure that the desired amount of processing gas is added to the processing chamber 212. As amount of fresh, unrecirculated processing gas as measured at the inlet pressure gauge 206 is reduced, the recirculation throttle valve 228 may be closed to ensure that sufficient processing gas is re-circulated back to the processing chamber 212 to maintain the desired processing chamber pressure. In one embodiment, the recirculation throttle valve 228 may be closed so that all of the processing gas is recirculated.

The processing gas mixture that is provided to the processing chamber 212 may include silane-based gases and hydrogen gas. Suitable examples of silane-based gases include, but are not limited to, mono-silane (SiH₄), di-silane (Si₂H₆), silicon tetrafluoride (SiF₄), silicon tetrachloride (SiCl₄), and dichlorosilane (SiH₂Cl₂), and the like. The gas ratio of the silane-based gas and H₂ gas may be maintained to control the reaction behavior of the gas mixture, thereby allowing a desired proportion of crystallization. For an intrinsic microcrystalline film, the amount of crystallization may be between about 20 percent and about 80 percent. In one embodiment, the ratio of silane-based gas to H₂ may be between about 1:20 to about 1:200. In another embodiment, the ratio may be about 1:80 to about 1:120. In another embodiment, the ratio may be about 1:100. Inert gas may also be provided to the processing chamber 212. The inert gas may include Ar, He, Xe, and the like. The inert gas may be supplied at a flow ratio of inert gas to H₂ gas of between about 1:10 to about 2:1.

Prior to depositing the intrinsic microcrystalline silicon layer, a thin seed layer of intrinsic microcrystalline silicon may be deposited using the silane-based gases and H₂ as discussed above. The gas mixture may have a ratio of silane-based gas to H₂ of about 1:100 to about 1:20000. In one embodiment, the ratio may be about 1:200 to about 1:1000. In another embodiment, the ratio may be about 1:500.

To ensure that the process chamber and recirculation system operate in an effective manner, a cleaning operation may be periodically conducted between two deposition operations. A cleaning operation will be discussed hereafter with reference to FIGS. 2 and 3, but it should be understood that the system shown in FIG. 4 is equally applicable.

At the startup of the cleaning operation, the shut-off valve 238 is closed and the recirculation throttle valve 228 is open. The gas source 208 then supplies a cleaning gas including SF₆, NF₃, or F₂ that flows along the conduit 204 to the remote plasma source 202 where a plasma is struck. The cleaning gas then passes through the process chamber 212, flows along the conduits 216, 220 to the particle trap/filter 224, and is eventually exhausted along the conduit 230 to abatement.

As shown in FIG. 3, as the cleaning gas passes through the particle trap/filter 300, the filter medium 304 inside the particle trap/filter 300 may also be heated by circulating a heating fluid along the heat exchange circuit 308. Residues that may have accumulated within the particle trap/filter 300 thus can be conveniently removed by a combined action of etching, evaporation and sublimation.

It is to be understood that while the invention has been described above with a single conduit containing the processing gas from the gas source, multiple conduits, each containing one or more processing gases may be used with each conduit having its own inlet pressure gauge that are collectively coupled with the recirculation throttle valve. In one embodiment, the dilution gas may be provided in its own, separate conduit directly to the remote plasma source. In another embodiment, the deposition gas may be provided from the gas source to the chamber through its own, separate conduit without passing through the remote plasma source. In yet another embodiment, the recirculated processing gas may be plumbed directly to the processing chamber rather than joining with the fresh, unrecirculated processing gases at a location between the remote plasma source and the processing chamber.

By recirculating process gases, the amount of fresh, unrecirculated processing gases may be reduced. By using less fresh, unrecirculated processing gas, the cost of depositing a layer onto a substrate by PECVD may be decreased because less money may be spent on fresh, unrecirculated processing gas. Thus, by recirculating exhausted process gas, a PECVD process may proceed in an efficient manner. In addition, because the recirculation system described above is fully compatible with periodical cleaning, its operation may be maintained at an optimal level in a cost effective manner.

While the foregoing is directed to embodiments of the present invention, other and further embodiments of the invention may be devised without departing from the basic scope thereof, and the scope thereof is determined by the claims that follow.

1. A particle trap/filter assembly, comprising:
a particle trap/filter body having an inlet adapted to be coupled with a chamber outlet and an outlet adapted to be coupled with a chamber inlet;
a filter medium disposed within the body between the inlet and the outlet; and
a heat exchange circuit coupled with the filter medium.

2. The assembly of claim 1, wherein the body comprises a first volume separated from a second volume by the filter medium and wherein the first volume at least partially surrounds the second volume.

3. The assembly of claim 2, wherein the first volume is adapted to be coupled with the chamber outlet.

4. The assembly of claim 2, wherein the second volume is adapted to be coupled with the chamber outlet.

5. The assembly of claim 1, wherein the heat exchange circuit is coupled with a source of cooling fluid.

6. The assembly of claim 1, wherein the heat exchange circuit is coupled with a source of heating fluid.

7. The assembly of claim 1, wherein the filter medium is made of a material selected from the group consisting of nickel, stainless steel, and combinations thereof.

8. The assembly of claim 1, wherein the heat exchange circuit is coupled with the filter medium by diffusion bonding or welding.

9. A plasma enhanced chemical vapor deposition apparatus, comprising a gas source, a processing chamber having a chamber outlet and a chamber inlet, and a recirculation system including the particle trap/filter assembly of claim 1.

10. The apparatus of claim 9, wherein the recirculation system includes a plurality of particle trap/filter assemblies.

11. A plasma enhanced chemical vapor deposition method, comprising:
providing a fresh, unrecirculated processing gas to a plasma enhanced chemical vapor deposition chamber having a chamber inlet and a chamber outlet;
performing a plasma enhanced chemical vapor deposition process;
exhausting the processing gas from the chamber;
flowing the exhausted processing gas through a particle trap/filter assembly, the assembly comprising a particle trap/filter body having an inlet coupled with the chamber outlet, an outlet coupled with the chamber inlet, a filter medium disposed within the body between the inlet and the outlet, and a heat exchange circuit coupled with the filter medium; and
recirculating at least a portion of the exhausted processing gas back to the chamber.

12. The method of claim 11, further comprising controlling the temperature of the assembly while the exhausted processing gas flows therethrough.

13. The method of claim 11, further comprising cooling the assembly.

14. The method of claim 11, wherein the heat exchange circuit is coupled with the filter medium by diffusion bonding or welding.

15. The method of claim 11, wherein the filtering medium comprises a material selected from the group consisting of nickel, stainless steel, and combinations thereof.

16. The method of claim 11, wherein the processing gas comprises hydrogen and silane.

17. The method of claim 16, wherein a ratio of hydrogen to silane is greater than about 20:1.

18. The method of claim 11, further comprising:
flowing a cleaning gas into the chamber;
exhausting the cleaning gas from the chamber;
flowing the exhausted cleaning gas through the assembly; and
recirculating at least a portion of the exhausted cleaning gas back to the chamber.

19. The method of claim 18, wherein the cleaning gas comprises a fluorine containing gas.

20. The method of claim 19, wherein the fluorine containing gas comprises SF₆.
